(19) United States
(12) Patent Application Publication
(10) Pub. No.: US 2018/0172523 A1
(43) Pub. Date: Jun. 21, 2018

(54) VOLTAGE DETECTING DEVICE, TEMPERATURE DETECTING DEVICE HAVING THE SAME, VOLTAGE DETECTING METHOD, AND TEMPERATURE DETECTING METHOD HAVING THE SAME

(71) Applicant: RENESAS ELECTRONICS CORPORATION, Tokyo (JP)

(72) Inventor: Masafumi TATEWAKI, Tokyo (JP)

(21) Appl. No.: 15/815,346

(22) Filed: Nov. 16, 2017

(30) Foreign Application Priority Data
Dec. 15, 2016 (JP) 2016-242904

(51) Int. Cl. G01K 7/01; H02J 7/00; H02M 7/48; G01K 1/14; G01K 1/02; G01R 19/25; G01R 19/22; G01R 19/165; H03F 1/02

(52) U.S. Cl. CPC G01K 7/01; H02J 7/0021; H02M 7/48; G01K 1/14; H03F 2200/234; G01R 19/2503; G01R 19/22; G01R 19/16576; H03F 1/0205; G01K 1/026

(57) ABSTRACT

According to an embodiment, a voltage detecting device includes: a first operational amplifier having an inversion input terminal to which first detection voltage is supplied and a non-inversion input terminal to which voltage of an external output terminal is supplied; a first transistor provided between the external output terminal and a reference voltage terminal and having a gate to which an output voltage of the first operational amplifier is applied; a second operational amplifier having an inversion input terminal to which second detection voltage is supplied and a non-inversion input terminal to which the voltage of the external output terminal is supplied; and a second transistor provided between the external output terminal and the reference voltage terminal and having a gate to which output voltage of the second operational amplifier is applied.

### CROSS-REFERENCE TO RELATED APPLICATIONS

The disclosure of Japanese Patent Application No. 2016-242904 filed on Dec. 15, 2016 including the specification, drawings and abstract is incorporated herein by reference in its entirety.

### BACKGROUND

The present invention relates to a voltage detecting device, a temperature detecting device having the same, a voltage detecting method, and a temperature detecting method having the same and relates to, for example, a voltage detecting device, a temperature detecting device having the same, a voltage detecting method, and a temperature detecting method having the same suitable for detecting voltages in a wide range with high precision.

For example, a driving device driving a polyphase motor or the like mounted in a vehicle is provided with a temperature detecting device detecting the highest temperature among temperatures measured at a plurality of measurement places. When a temperature exceeding a permitted temperature is detected by the temperature detecting device, by stopping the driving of the polyphase motor or shifting the mode to a safe mode, the driving device can be protected from overheating.

A related art is disclosed in patent literature 1. A temperature detecting circuit disclosed in the patent literature 1 has a plurality of ideal diodes to which a plurality of voltages corresponding to a plurality of temperatures detected by a plurality of temperature detecting elements are supplied, and the maximum or minimum voltage corresponding to the highest temperature is selectively output among the plurality of voltages from the plurality of ideal diodes.

### RELATED ART LITERATURE

### Patent Literature

Patent Literature 1: Japanese Patent Publication No. 5444307

### SUMMARY

In the configuration of the patent literature 1, each ideal diode is comprised of an operational amplifier amplifying a potential difference between a voltage from a temperature detecting element and a voltage of an external output terminal of a temperature detecting circuit, and a diode provided in a forward direction between an output terminal of the operational amplifier and the external output terminal of the temperature detecting circuit. Consequently, in the configuration of the patent literature 1, the lower limit of an output dynamic range becomes higher only by the amount of a step-down voltage (about 0.7V) of the diode, and the output dynamic range becomes narrower. As a result, the configuration of the patent literature 1 has a problem that voltages in a wide range cannot be detected with high precision. The other problem and novel features will become apparent from the description of the specification and the appended drawings.

According to an embodiment, a voltage detecting device includes: a first operational amplifier having an inversion input terminal to which a first detection voltage is supplied and a non-inversion input terminal to which a voltage corresponding to a voltage of an external output terminal is supplied; a first MOS transistor provided between the external output terminal and a reference voltage terminal and having a gate to which an output voltage of the first operational amplifier is applied; a second operational amplifier having an inversion input terminal to which a second detection voltage is supplied and a non-inversion input terminal to which a voltage corresponding to the voltage of the external output terminal is supplied; and a second MOS transistor provided between the external output terminal and the reference voltage terminal and having a gate to which an output voltage of the second operational amplifier is applied.

According to another embodiment, a semiconductor device includes: a driver switching on/off of a switch element provided between a power supply and a load; a control circuit controlling the driver; a power supply circuit supplying power supply voltage to the driver and the control circuit; and a temperature detecting device. The temperature detecting device includes: a first thermometry unit generating a first detection voltage according to temperature of the driver; a second thermometry unit generating a second detection voltage according to temperature of the power supply circuit; a first operational amplifier having an inversion input terminal to which the first detection voltage is supplied and a non-inversion input terminal to which a voltage corresponding to a voltage of an external output terminal is supplied; a first MOS transistor provided between the external output terminal and a reference voltage terminal and having a gate to which an output voltage of the first operational amplifier is applied; a second operational amplifier having an inversion input terminal to which the second detection voltage is supplied and a non-inversion input terminal to which a voltage corresponding to the voltage of the external output terminal is supplied; and a second MOS transistor provided between the external output terminal and the reference voltage terminal and having a gate to which an output voltage of the second operational amplifier is applied.

According to another embodiment, a voltage detecting method includes the steps of: amplifying a potential difference between a first detection voltage supplied to an inversion input terminal and a voltage corresponding to a voltage of an external output terminal supplied to a non-inversion input terminal by using a first operational amplifier; controlling on/off of a first MOS transistor provided between the external output terminal and a reference voltage terminal in accordance with a result of amplification of the first operational amplifier; amplifying a potential difference between a second detection voltage supplied to an inversion input terminal and a voltage corresponding to a voltage of the external output terminal supplied to a non-inversion input terminal by using a second operational amplifier; and controlling on/off of a second MOS transistor provided between the external output terminal and the reference voltage terminal in accordance with a result of amplification of the second operational amplifier.

According to the embodiments, a voltage detecting device capable of detecting a voltage in a wide range with high precision, a temperature detecting device having the same, a voltage detecting method, and a temperature detecting method having the same can be provided.

### BRIEF DESCRIPTION OF THE DRAWINGS

FIG. 1 is a diagram illustrating a configuration example of a temperature detecting device according to a first embodiment.

FIG. 2 is a circuit diagram illustrating a first concrete configuration example of an operational amplifier provided for the temperature detecting device depicted in FIG. 1.

FIG. 3 is a circuit diagram illustrating a second concrete configuration example of the operational amplifier provided for the temperature detecting device depicted in FIG. 1.

FIG. 4 is a diagram illustrating a configuration example of a temperature detection system in which the temperature detecting device depicted in FIG. 1 is mounted.

FIG. 5 is a diagram illustrating a modification of the temperature detecting device depicted in FIG. 1.

FIG. 6 is a diagram illustrating a configuration example of a temperature detecting device according to a second embodiment.

FIG. 7 is a diagram illustrating a modification of the temperature detecting device depicted in FIG. 6.

FIG. 8 is a diagram illustrating a configuration example of a temperature detecting device according to a third embodiment.

FIG. 9 is a diagram illustrating a modification of the temperature detecting device depicted in FIG. 8.

### DETAILED DESCRIPTION

Hereinafter, embodiments will be described with reference to the drawings. Since the drawings are simplified, the technical scope of the embodiments shall not be interrupted narrowly on the basis of the description of the drawings. The same reference numeral is designated to the same elements and repetitive description will not be given.

In the following embodiments, when it is necessary for convenience, an embodiment will be described by being divided into a plurality of sections or embodiments. Unless otherwise clearly specified, they are not non-related to one another but have relations such as modification, application, detailed description, and supplementary explanation in which one is a part or all of the other. In the following embodiments, in the case of referring to the number of elements and the like (including the number of pieces, numerical value, quantity, and range), except for the case where it is clearly mentioned, the case where the invention is principally clearly limited to a specific value, and the like, the invention is not limited to the specific value. The number may be larger or smaller than the specific value.

Further, in the following embodiments, obviously, components (including operation steps) are not always necessary except for the case where it is clearly mentioned, the case where it is considered that a component is principally clearly necessary, and the like. Similarly, in the following embodiments, when shape, position relation, and the like of components are mentioned, they substantially include shape and the like close or similar to them except for the case where it is clearly mentioned, the case where it is considered that the shape and the like are not principally clearly similar. This is similarly applied also to the number (including the number of pieces, numerical value, quantity, and range).

### First Embodiment

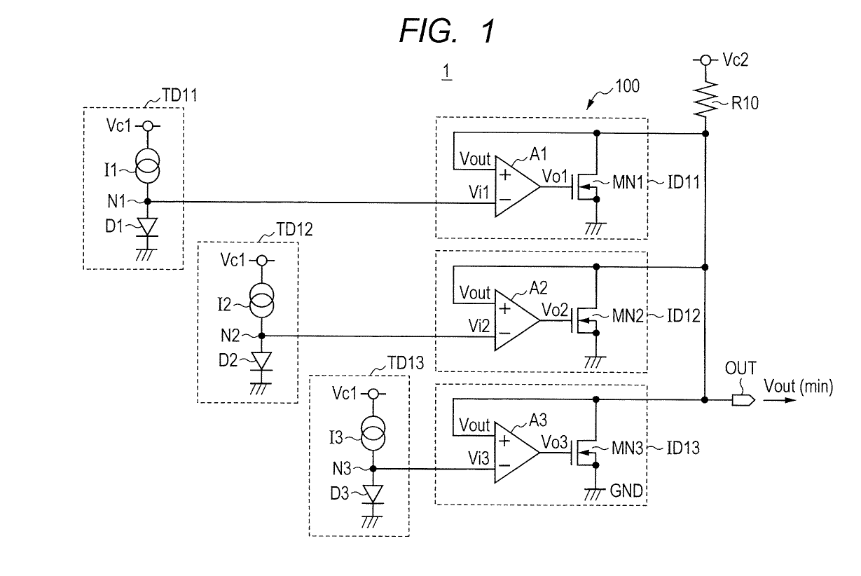

FIG. 1 is a block diagram illustrating a configuration example of a temperature detecting device according to a first embodiment. The temperature detecting device according to the embodiment detects a voltage corresponding to the highest temperature from a plurality of voltages corresponding to a plurality of temperatures to be measured by using a voltage detecting device. By assuring a wide output dynamic range, the voltage detecting device can detect the lowest voltage from the plurality of voltages in a wide range with high precision. Consequently, the temperature detecting device provided with the voltage detecting device can detect temperatures in a wide range with high precision. Hereinafter, it will be concretely described.

As illustrated in FIG. 1, a temperature detecting device 1 has thermometry units TD11 to TD13, ideal diodes ID11 to ID13, and a resistive element R10. By the ideal diodes ID11 to ID13 and the resistive element R10, a voltage detecting device 100 detecting the lowest voltage in output voltages of the thermometry units TD11 to TD13 is configured.

### Thermometry Units TD11 to TD13

The thermometry unit TD11 has a constant current supply I1 and a diode D1. The constant current supply I1 is provided between a power supply voltage terminal Vc1 and a node N1. The anode of the diode D1 is coupled to the node N1, and the cathode of the diode D1 is coupled to a reference voltage terminal GND. Consequently, constant current output from the constant current supply I1 flows from the anode to the cathode of the diode D1. The thermometry unit TD11 outputs the voltage of the node N1 indicative of a step-down voltage of the diode D1 as a detection voltage Vi1.

The thermometry unit TD12 has a constant current supply I2 and a diode D2. The constant current supply I2 is provided between the power supply voltage terminal Vc1 and a node N2. The anode of the diode D2 is coupled to the node N2, and the cathode of the diode D2 is coupled to the reference voltage terminal GND. Consequently, constant current output from the constant current supply I2 flows from the anode to the cathode of the diode D2. The thermometry unit TD12 outputs the voltage of the node N2 indicative of a step-down voltage of the diode D2 as a detection voltage Vi2.

The thermometry unit TD13 has a constant current supply 13 and a diode D3. The constant current supply 13 is provided between the power supply voltage terminal Vc1 and a node N3. The anode of the diode D3 is coupled to the node N3, and the cathode of the diode D3 is coupled to the reference voltage terminal GND. Consequently, constant current output from the constant current supply 13 flows from the anode to the cathode of the diode D3. The thermometry unit TD13 outputs the voltage of the node N3 indicative of a step-down voltage of the diode D3 as a detection voltage Vi3.

It is known that the step-down voltages of the diodes D1 to D3 have a negative temperature characteristic. Concretely, as the temperature becomes higher, the step-down voltages of the diodes D1 to D3 decrease. As the temperature becomes lower, the step-down voltages increase. Therefore, by disposing the diodes D1 to D3 used as temperature detecting elements near or inside of an object to be measured, the thermometry units TD11 to TD13 can output the detection voltages Vi1 to Vi3 according to the temperature of the object to be measured (more specifically, having a negative temperature characteristic with respect to the temperature of the object to be measured).

For example, the temperature detecting device 1 is mounted in a load drive system driving a load. The diodes D1 to D3 as temperature detecting elements provided for the temperature detecting device 1 are disposed in or near drivers (a high-side driver and a low-side driver) switching on/off of a switch provided between a power supply and a load, a power supply circuit supplying power supply voltage to the drivers, and the like. With the configuration, the thermometry units TD11 to TD13 can detect temperature of the high-side driver, the low-side driver, and the power supply circuit. The details of an example of mounting the temperature detecting device 1 will be described later.

### Voltage Detecting Device 100

The voltage detecting device 100 selects a detection voltage indicating the lowest value from the detection voltages Vi1 to Vi3 of the thermometry units TD11 to TD13 and outputs the selected detection voltage as voltage Vout. Hereinafter, it will be concretely described.

The ideal diode ID11 is comprised of an operational amplifier A1 and an N-channel MOS transistor (hereinafter, simply called transistor) MN1. In the operational amplifier A1, the detection voltage Vi1 of the thermometry unit TD11 is supplied to an inversion input terminal (INN), the voltage Vout of an external output terminal OUT is supplied to a non-inversion input terminal (INP), and voltage Vo1 is output from an output terminal (TO). In the transistor MN1, the source is coupled to the reference voltage terminal GND, the drain is coupled to the external output terminal OUT, and the output voltage Vo1 of the operational amplifier A1 is applied to the gate.

The ideal diode ID12 is comprised of an operational amplifier A2 and an N-channel MOS transistor (hereinafter, simply called transistor) MN2. In the operational amplifier A2, the detection voltage Vi2 of the thermometry unit TD12 is supplied to an inversion input terminal, the voltage Vout of the external output terminal OUT is supplied to a non-inversion input terminal, and voltage Vo2 is output from an output terminal. In the transistor MN2, the source is coupled to the reference voltage terminal GND, the drain is coupled to the external output terminal OUT, and the output voltage Vo2 of the operational amplifier A2 is applied to the gate.

The ideal diode ID13 is comprised of an operational amplifier A3 and an N-channel MOS transistor (hereinafter, simply called transistor) MN3. In the operational amplifier A3, the detection voltage Vi3 of the thermometry unit TD13 is supplied to an inversion input terminal, the voltage Vout of the external output terminal OUT is supplied to the non-inversion input terminal, and voltage Vo3 is output from an output terminal. In the transistor MN3, the source is coupled to the reference voltage terminal GND, the drain is coupled to the external output terminal OUT, and the output voltage Vo3 of the operational amplifier A3 is applied to the gate.

Between a power supply voltage terminal Vc2 and the external output terminal OUT, the resistive element R10 is provided.

Subsequently, the operation of the voltage detecting device 100 will be described.

First, the operation of the ideal diode ID11 will be described.

For example, in the case where detection voltage Vi1>voltage Vout, the voltage Vo1 of the L level is output from the operational amplifier A1, so that the transistor MN1 is turned off. That is, a negative feedback path of the operational amplifier A1 is interrupted. Consequently, the voltage Vout is maintained at a value indicated until then without being influenced by the detection voltage Vi1. In other words, the detection voltage Vi1 is not transmitted to the external output terminal OUT.

On the other hand, in the case where detection voltage Vi1≤voltage Vout, the voltage Vo1 of the H level is output from the operational amplifier A1, so that the transistor MN1 is turned on. That is, a negative feedback path of the operational amplifier A1 is formed. Consequently, by adjusting the voltage Vo1 by the operational amplifier A1, the voltage Vout is adjusted so as to indicate the same value as the detection voltage Vi1. In other words, the detection voltage Vi1 is transmitted to the external output terminal OUT.

The operation of the ideal diode ID12 is basically the same as that of the ideal diode ID11. That is, in the case where detection voltage Vi2>voltage Vout, the detection voltage Vi2 is not transmitted to the external output terminal OUT. In the case where detection voltage Vi2≤voltage Vout, the detection voltage Vi2 is transmitted to the external output terminal OUT.

The operation of the ideal diode ID13 is basically the same as that of the ideal diode ID11. That is, in the case where detection voltage Vi3>voltage Vout, the detection voltage Vi3 is not transmitted to the external output terminal OUT. In the case where detection voltage Vi3≤voltage Vout, the detection voltage Vi3 is transmitted to the external output terminal OUT.

Therefore, the voltage Vout of the external output terminal OUT indicates the same value as the detection voltage indicating the lowest value among the detection voltages Vi1 to Vi3. As described above, each of the step-down voltages of the diodes D1 to D3 provided for the thermometry units TD11 to TD13 has a negative temperature characteristic. That is, the detection voltage output from the thermometry unit which detects the highest temperature among the thermometry units TD11 to TD13 indicates the lowest value. Consequently, the temperature detecting device 1 outputs the detection voltage output from the thermometry unit which detects the highest temperature among the thermometry units TD11 to TD13 as the detection voltage Vout.

As described above, the temperature detecting device 1 is provided with the N-channel MOS transistors MN1 to MN3 coupling the output terminals of the operational amplifiers A1 to A3 and the external output terminal OUT by the gates and the drains. A source-drain voltage in a saturation region in the N-channel MOS transistor is about 0.2V. Consequently, the lower limit of the range in which the detection voltages Vi1 to Vi3 are transmitted to the external output terminal OUT with high precision is a low value to a degree that about 0.2V is added to the reference voltage GND (=0V). That is, the temperature detecting device 1 can assure a wide output dynamic range. Therefore, the temperature detecting device 1 can detect the temperatures in the wide range with high precision.

Further, in the temperature detecting device 1, the output terminals of the operational amplifiers A1 to A3 are coupled to the gate electrodes of the N-channel MOS transistors MN1 to MN3. Consequently, a current path extending through the output terminals of the operational amplifiers A1 to A3 and the transistors MN1 to MN3 is not formed. As a result, the operational amplifiers A1 to A3 can have a simple configuration of low output current capability, so that the temperature detecting device 1 can realize smaller scale, lower cost, and lower power consumption. Hereinafter, concrete configuration examples of the operational amplifiers A1 to A3 will be described.

### First Concrete Configuration Example of Operational Amplifier A1

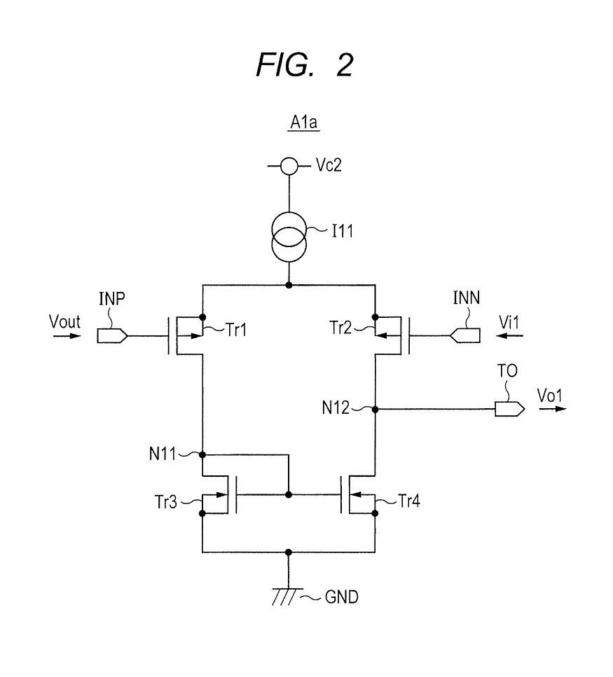

FIG. 2 is a circuit diagram illustrating a first concrete configuration example of the operational amplifier A1 as an operational amplifier A1a.

As illustrated in FIG. 2, the operational amplifier A1a has a constant current supply I11, P-channel MOS transistors (hereinafter, simply called transistors) Tr1 and Tr2, and N-channel MOS transistors (hereinafter, simply called transistors) Tr3 and Tr4.

The input terminal of the constant current supply I11 is coupled to the power supply voltage terminal Vc2. In the transistor Tr1, the source is coupled to the output terminal of the constant current supply I11, the drain is coupled to a node N11, and the gate is coupled to a non-inversion input terminal INP. In the transistor Tr2, the source is coupled to the output terminal of the constant current supply I11, the drain is coupled to a node N12, and the gate is coupled to the inversion input terminal INN. That is, a differential circuit is comprised of the constant current supply I11 and the transistors Tr1 and Tr2.

In the transistor Tr3, the source is coupled to the reference voltage terminal GND, and the drain and gate are coupled to the node N11. In the transistor Tr4, the source is coupled to the reference voltage terminal GND, the drain is coupled to the node N12, and the gate is coupled to the node N11. The node N12 is coupled to an output terminal TO of the operational amplifier A1a. That is, a current mirror circuit is comprised of the transistors Tr3 and Tr4.

To the transistors Tr1 and Tr2, a drain current obtained by distributing the output current of the constant current supply I11 in accordance with the voltages Vout and Vi1 supplied to the input terminals INP and INN flows.

To the transistor Tr4, drain current proportional to drain current flowing in the transistor Tr3 flows. For example, to the transistor Tr4, drain current which is substantially the same as the drain current flowing in the transistor Tr3 flows.

To the transistor Tr3, the drain current flowing in the transistor Tr1 flows as it is as the drain current. Consequently, to the transistor Tr4, the drain current which is substantially the same as the drain current flowing in the transistor Tr1 flows. Therefore, to the output terminal TO, the current which is the difference between the drain current of the transistor Tr2 and the drain current of the transistor Tr4 flows.

For example, when the voltage Vout supplied to the non-inversion input terminal INP is higher than the voltage Vi1 supplied to the inversion input terminal INN, the drain current of the transistor Tr2 becomes larger than the drain current of the transistor Tr4. Therefore, current flows from the output terminal TO so as to be discharged to the outside of the operational amplifier A1a. The output terminal TO of the operational amplifier A1a is coupled to the gate of the transistor MN1. Consequently, charges of the current discharged from the output terminal TO to the outside of the operational amplifier A1a are accumulated in the gate of the transistor MN1. By the above, the gate voltage of the transistor MN1 increases close to the source voltage (power supply voltage Vc2) of the transistor Tr2 and indicates the H level.

On the other hand, when the voltage Vout supplied to the non-inversion input terminal INP is lower than the voltage Vi1 supplied to the inversion input terminal INN, the drain current of the transistor Tr2 becomes smaller than the drain current of the transistor Tr4. Therefore, the current flows from the output terminal TO so as to be sucked into the operational amplifier A1a. The output terminal TO of the operational amplifier A1a is coupled to the gate of the transistor MN1. Consequently, by the current sucked from the output terminal TO to the inside of the operational amplifier A1a, charges accumulated in the gate of the transistor MN1 are drawn. Therefore, the gate voltage of the transistor MN1 decreases close to the source voltage (reference voltage GND) of the transistor Tr4 and indicates the L level.

Since the first concrete configuration example of the operational amplifiers A2 and A3 is similar to that of the operational amplifier A1a, the description will not be repeated.

When a load in which steady current does not flow like the gate electrode of the transistor MN1 is coupled to the output terminal, the operational amplifier A1a can execute amplifying operation with a low offset voltage. Since the operational amplifier A1a is comprised of smaller number of components as compared with an operational amplifier A1b which will be described later, the circuit scale can be reduced and the power consumption can be decreased. As a result, smaller scale, lower cost, and lower power consumption of the temperature detecting device 1 can be realized.

### Second Concrete Configuration Example of Operational Amplifier A1

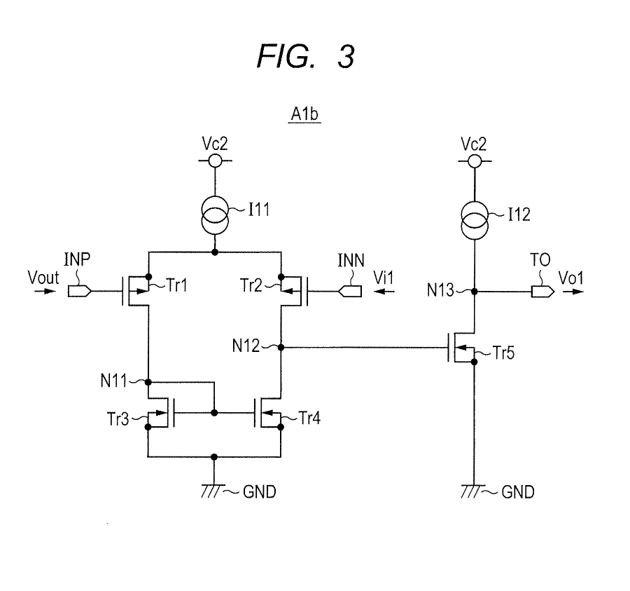

FIG. 3 is a circuit diagram illustrating a second concrete configuration example of the operational amplifier A1 as the operational amplifier A1b.

As illustrated in FIG. 3, the operational amplifier A1b further includes a constant current supply I12 and an n-channel MOS transistor (hereinafter, simply called a transistor) Tr5 in addition to the configuration of the operational amplifier A1a.

The input terminal of the constant current supply I11 is coupled to the power supply voltage terminal Vc2. In the transistor Tr5, the source is coupled to the reference voltage terminal GND, the drain is coupled to the output terminal of the constant current supply I11, and the gate is coupled to the node N12. A node N13 between the output terminal of the constant current supply I12 and the drain of the transistor Tr5 is coupled to the output terminal TO of the operational amplifier A1b. That is, the operational amplifier A1b further includes a source ground amplification circuit made by the constant current supply I12 and the transistor Tr5.

Since the other configuration of the operational amplifier A1b is similar to that in the case of the operational amplifier A1a, the description will not be repeated. Since the second concrete configuration example of the operational amplifiers A2 and A3 is similar to that in the case of the operational amplifier A1b, the description will not be repeated.

The operational amplifier A1b can execute amplifying operation with low offset voltage also in the case where a load in which stationary current flows such as a constant current supply or a resistor is coupled to the output terminal.

### Application Example of Temperature Detecting Device 1

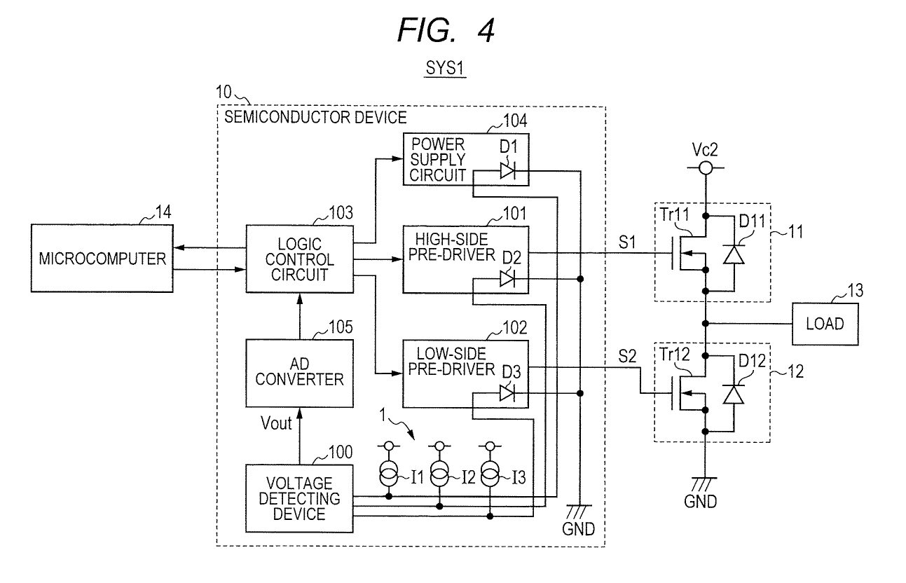

Subsequently, an application example of the temperature detecting device 1 will be described. FIG. 4 is a diagram illustrating a configuration example of a load driving system SYS1 in which the temperature detecting device 1 is mounted.

As illustrated in FIG. 4, the load driving system SYS1 is a system driving a load 13 such as a polyphase motor mounted in a vehicle and has a semiconductor device 10, a high-side switch 11, a low-side switch 12, and a microcomputer 14. A load driving device is comprised of the semiconductor device 10, the high-side switch 11, and the low-side switch 12. In FIG. 4, the load 13 is also illustrated.

In the load driving system SYS1, the semiconductor device 10 controls on/off of switching elements (the high-side switch 11 and the low-side switch 12) provided between the power supply and the load 13 on the basis of an instruction from the microcomputer 14. By the control, supply of power to the load 13 is controlled.

The high-side switch 11 is provided between the power supply voltage terminal (power supply) Vc2 and the load 13 and controls the on/off by a switch signal S1 from the semiconductor device 10. Concretely, the high-side switch 11 is comprised of an N-channel MOS transistor (hereinafter, called a transistor) Tr11 and a diode D11. In the transistor Tr11, the source is coupled to the load 13, the drain is coupled to the power supply voltage terminal Vc2, and the switch signal S1 from the semiconductor device 10 is applied to the gate. The anode of the diode D11 is coupled to the source of the transistor Tr11, and the cathode of the diode D11 is coupled to the drain of the transistor Tr11.

The low-side switch 12 is provided between the reference voltage terminal GND and the load 13 and its on/off is controlled by a switch signal S2 from the semiconductor device 10. Concretely, the low-side switch 12 is comprised of an N-channel MOS transistor (hereinafter, called a transistor) Tr12 and a diode D12. In the transistor Tr12, the source is coupled to the reference voltage terminal GND, the drain is coupled to the load 13, and the switch signal S2 from the semiconductor device 10 is applied to the gate. The anode of the diode D12 is coupled to the source of the transistor Tr12, and the cathode of the diode D12 is coupled to the drain of the transistor Tr12.

The semiconductor device 10 is a device controlling the switching operation of each of the high-side switch 11 and the low-side switch 12. Concretely, the semiconductor device 10 has a high-side pre-driver 101, a low-side pre-driver 102, a logic control circuit 103, a power supply circuit 104, and an AD converter 105. Further, the semiconductor device 10 is provided with the temperature detecting device 1.

The high-side pre-driver 101 outputs the switch signal S1 for switching the on/off of the high-side switch 11 on the basis of a control signal from the logic control circuit 103. The low-side pre-driver 102 outputs the switch signal S2 for switching the on/off of the low-side switch 12 on the basis of a control signal from the logic control circuit 103. The power supply circuit 104 supplies the power supply voltage to each of the function blocks of the semiconductor device 10. The logic control circuit 103 controls the high-side pre-driver 101, the low-side pre-driver 102, and the power supply circuit 104 on the basis of an instruction from the microcomputer 14.

In the high-side pre-driver 101, the low-side pre-driver 102, and the power supply circuit 104 provided in the semiconductor device 10, the possibility that large current flows at the time of abnormality and heat generation occurs is high.

In the high-side pre-driver 101, the low-side pre-driver 102, and the power supply circuit 104, the diodes D1, D2, and D3 provided for the thermometry units TD11, TD12, and TD13 of the temperature detecting device 1 are mounted, respectively. The temperature detecting device 1 outputs, as the detection voltage Vout, the detection voltage (output of the voltage detecting device 100) output from the thermometry unit which detects the highest temperature in the thermometry units TD11 to TD13. In other words, the temperature detecting device 1 outputs, as the detection voltage Vout, the detection voltage corresponding to the highest temperature in the power supply circuit 104, the high-side pre-driver 101, and the low-side pre-driver 102.

The AD converter 105 converts the detection voltage Vout output from the temperature detecting device 1 to a digital signal. The logic control circuit 103 transmits an AD conversion result to the microcomputer 14. The microcomputer 14 always or periodically monitors an AD conversion result from the logic control circuit 103 and, on the basis of the result, instructs the control of each of the function blocks of the semiconductor device 10 to the logic control circuit 103.

For example, when it is determined that any of the temperatures of the power supply circuit 104, the high-side pre-driver 101, and the low-side pre-driver 102 exceeds allowable temperature from a detection result (AD conversion result) of the temperature detecting device 1, the microcomputer 14 stops the switching operation of the high-side switch 11 and the low-side switch 12 by the semiconductor device 10.

In designing of the high-side pre-driver 101, the low-side pre-driver 102, and the power supply circuit 104, it is necessary to thicken a wire or dispose the function blocks near an external coupling terminal in consideration of the large current flowing at the time of abnormality. Consequently, it is difficult to dispose the function blocks collectively. Therefore, the possibility that the function blocks having high heat generation property such as the high-side pre-driver 101, the low-side pre-driver 102, and the power supply circuit 104 are disposed dispersedly is high.

However, even in the case where the function blocks of high heat generation property are disposed dispersedly, by disposing a temperature detecting element in a function block to be measured, heat generation in any of function blocks to be measured can be detected. As a result, the switching operation of the high-side switch 11 and the low-side switch 12 by the semiconductor device 10 can be stopped promptly.

In the embodiment, the case where the three thermometry units TD11 to TD13 are provided has been described as an example. However, the present invention is not limited to the case. The configuration can be properly changed to a configuration in which thermometry units of an arbitrary number of two or larger are provided. In this case, ideal diodes of a number according to the number of thermometry units have to be provided.

In the embodiment, the case where a diode is used as a temperature detecting element has been described as an example. However, the present invention is not limited to the embodiment. For example, as the temperature detecting element, an NTC (Negative Temperature Coefficient) thermistor may be used in place of the diode.

In the embodiment, the case where the temperature detecting device 1 is comprised of the voltage detecting device 100 together with the thermometry units TD11 to TD13 has been described as an example. However, the invention is not limited to the case. The voltage detecting device 100 may be used as a single device or may be used together with another voltage detecting circuit. The voltage detecting device 100 can precisely detect a voltage indicating the lowest value from a plurality of voltages in a wide range. Smaller scale, lower cost, and lower power consumption can be also realized.

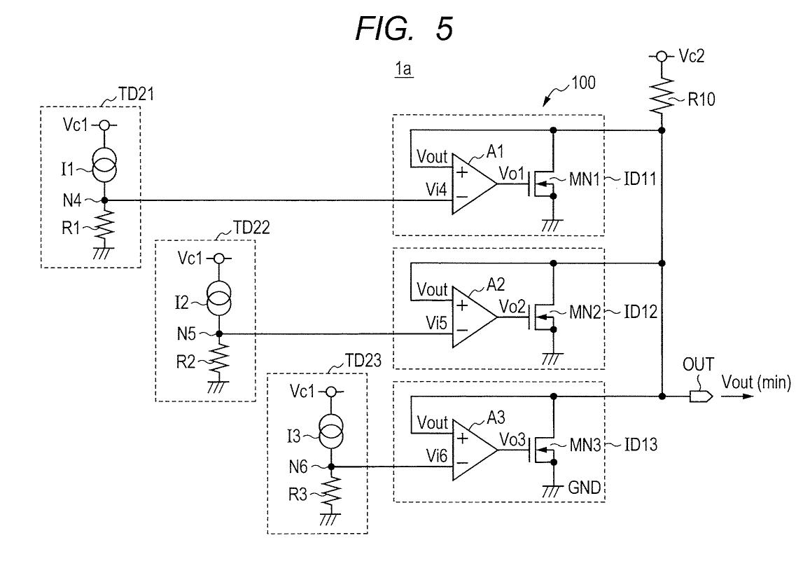

Further, in the embodiment, the case where the temperature detecting device 1 outputs, as the detection voltage Vout, the detection voltage output from the thermometry unit which detects the highest temperature from the plurality of thermometry units has been described as an example. However, the invention is not limited to the case. The temperature detecting device 1 can properly change the configuration to a configuration of outputting, as the detection voltage Vout, the detection voltage output from the thermometry unit which detects the lowest temperature from the plurality of thermometry units. Hereinafter, it will be concretely described with reference to FIG. 5.

### Modification of Temperature Detecting Device 1

FIG. 5 is a block diagram illustrating a modification of the temperature detecting device 1 as a temperature detecting device 1a.

In comparison to the temperature detecting device 1, the temperature detecting device 1a has thermometry units TD21 to TD23 generating detection voltages Vi4 to Vi6 having a positive temperature characteristic in place of the thermometry units TD11 to TD13 generating the detection voltages Vi1 to Vi3 having a negative temperature characteristic. Hereinafter, it will be concretely described.

The thermometry unit TD21 has, as a temperature detecting element, a metal resistor R1 in place of the diode D1. To the metal resistor R1, constant current output from the constant current supply I1 flows via a node N4. The thermometry unit TD21 outputs the voltage of the node N4 generated by the voltage drop of the metal resistor R1 as the detection voltage Vi4.

The thermometry unit TD22 has a metal resistor R2 in place of the diode D2 as a temperature detecting element. To the metal resistor R2, constant current output from the constant current supply I2 flows via a node N5. The thermometry unit TD22 outputs, as the detection voltage Vi5, the voltage of the node N5 generated by voltage drop of the metal resistor R2.

The thermometry unit TD23 has a metal resistor R3 in place of the diode D3 as a temperature detecting element. To the metal resistor R3, constant current output from the constant current supply 13 flows via a node N6. The thermometry unit TD23 outputs, as the detection voltage Vi6, the voltage of the node N6 generated by voltage drop of the metal resistor R3.

It is known that the step-down voltage in each of the metal resistors R1 to R3 has a positive temperature characteristic. Concretely, as the temperature becomes higher, the step-down voltage in each of the metal resistors R1 to R3 increases. As the temperature becomes lower, the step-down voltage decreases. Therefore, by disposing the metal resistors R1 to R3 used as the temperature detecting elements near or inside of an object to be measured, the thermometry units TD21 to TD23 can output the detection voltages Vi4 to Vi6 according to the temperature of the object to be measured (more specifically, having a positive temperature characteristic with respect to the temperature of the object to be measured).

To the inversion input terminals of the operational amplifiers A1 to A3, the detection voltages Vi4 to Vi6 from the thermometry units TD21 to TD23 are supplied, respectively. Since the other configuration of the temperature detecting device 1a is similar to that of the temperature detecting device 1, the description will not be repeated.

The voltage Vout of the external output terminal OUT has the same value as the detection voltage indicating the lowest value in the detection voltages Vi4 to Vi6. As described above, any of the step-down voltages of the metal resistors R1 to R3 provided for the thermometry units TD21 to TD23 have a positive temperature characteristic. That is, the detection voltage output from the thermometry unit which detects the lowest temperature in the thermometry units TD21 to TD23 indicates the lowest value. Consequently, the temperature detecting device 1a outputs, as the detection voltage Vout, the detection voltage output from the thermometry unit which detects the lowest temperature among the thermometry units TD21 to TD23.

The temperature detecting device 1a also can produce effects similar to those in the case of the temperature detecting device 1. That is, since a wide output dynamic range can be assured, the temperature detecting device 1a can precisely detect the temperatures in a wide range. Further, since the operational amplifiers A1 to A3 can have the simple configuration with low output current capability, the temperature detecting device 1a can realize smaller scale, lower cost, and lower power consumption.

Although the case of using the metal resistors as the temperature detecting elements has been described as an example in the example of FIG. 5, the invention is not limited to the case. For example, as the temperature detecting element, a PTC (Positive Temperature Coefficient) thermistor may be used in place of the metal resistor.

### Second Embodiment

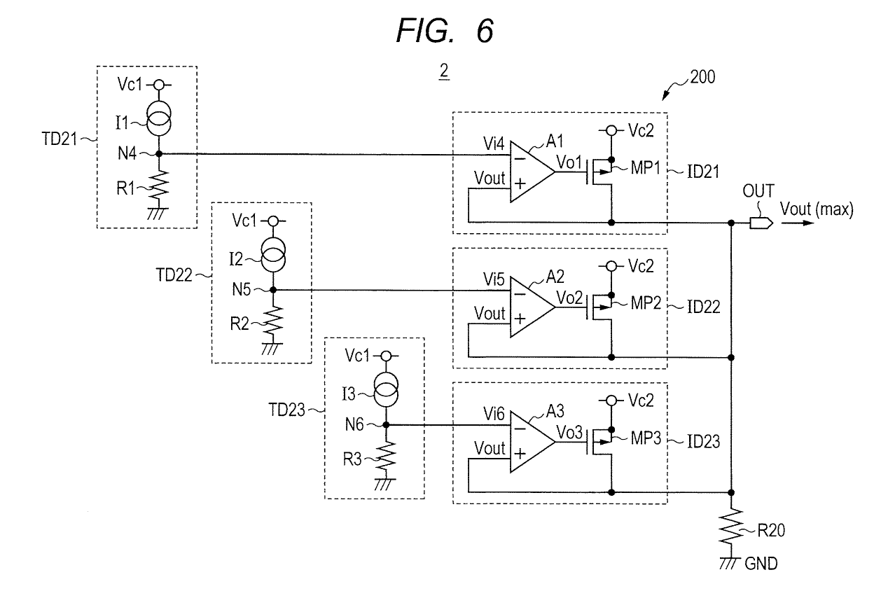

FIG. 6 is a block diagram illustrating a configuration example of a temperature detecting device 2 according to a second embodiment.

In comparison to the temperature detecting device 1, the temperature detecting device 2 has the thermometry units TD21 to TD23 generating the detection voltages Vi4 to Vi6 having a positive temperature characteristic in place of the thermometry units TD11 to TD13 generating the detection voltages Vi1 to Vi3 having a negative temperature characteristic. The temperature detecting device 2 has a voltage detecting device 200 selecting and outputting maximum detection voltage from a plurality of detection voltages in place of the voltage detecting device 100 selecting and outputting minimum detection voltage from a plurality of detection voltages. Hereinafter, it will be concretely described.

Since the details of the thermometry units TD21 to TD23 are already disclosed in FIG. 5, the description will not be repeated.

In comparison to the voltage detecting device 100, the voltage detecting device 200 has ideal diodes ID21 to ID23 having P-channel MOS transistors in place of the ideal diodes ID11 to ID13 having N-channel MOS transistors and has a resistive element R20 in place of the resistive element R10.

The ideal diode ID21 is comprised of the operational amplifier A1 and a P-channel MOS transistor (hereinafter, simply called transistor) MP1. In the operational amplifier A1, the detection voltage Vi4 from the thermometry unit TD21 is supplied to an inversion input terminal (INN), the voltage Vout of the external output terminal OUT is supplied to the non-inversion input terminal (INP), and the voltage Vo1 is output from the output terminal (TO). In the transistor MP1, the source is coupled to the power supply voltage terminal Vc2, the drain is coupled to the external output terminal OUT, and the output voltage Vo1 of the operational amplifier A1 is applied to the gate.

The ideal diode ID22 is comprised of the operational amplifier A2 and a P-channel MOS transistor (hereinafter, simply called transistor) MP2. In the operational amplifier A2, the detection voltage Vi5 of the thermometry unit TD22 is supplied to an inversion input terminal, the voltage Vout of the external output terminal OUT is supplied to a non-inversion input terminal, and the voltage Vo2 is output from an output terminal. In the transistor MP2, the source is coupled to the power supply voltage terminal Vc2, the drain is coupled to the external output terminal OUT, and the output voltage Vo2 of the operational amplifier A2 is applied to the gate.

The ideal diode ID23 is comprised of the operational amplifier A3 and a P-channel MOS transistor (hereinafter, simply called transistor) MP3. In the operational amplifier A3, the detection voltage Vi6 from the thermometry unit TD23 is supplied to an inversion input terminal, the voltage Vout of the external output terminal OUT is supplied to the non-inversion input terminal, and the voltage Vo3 is output from the output terminal. In the transistor MP3, the source is coupled to the power supply voltage terminal Vc2, the drain is coupled to the external output terminal OUT, and the output voltage Vo3 of the operational amplifier A3 is applied to the gate.

Between the reference voltage terminal GND and the external output terminal OUT, the resistive element R20 is provided.

Subsequently, the operation of the voltage detecting device 200 will be described.

First, the operation of the ideal diode ID2l will be described.

For example, in the case where detection voltage Vi4<voltage Vout, the voltage Vo1 of the H level is output from the operational amplifier A1, so that the transistor MP1 is turned off. That is, a negative feedback path of the operational amplifier A1 is interrupted. Consequently, the voltage Vout is maintained at a value indicated until then without being influenced by the detection voltage Vi4. In other words, the detection voltage Vi4 is not transmitted to the external output terminal OUT.

On the other hand, in the case where detection voltage Vi4≥voltage Vout, the voltage Vo1 of the L level is output from the operational amplifier A1, so that the transistor MP1 is turned on. That is, a negative feedback path of the operational amplifier A1 is formed. Consequently, by adjusting the voltage Vo1 by the operational amplifier A1, the voltage Vout is adjusted so as to indicate the same value as the detection voltage Vi4. In other words, the detection voltage Vi4 is transmitted to the external output terminal OUT.

The operation of the ideal diode ID22 is basically the same as that of the ideal diode ID21. That is, in the case where detection voltage Vi5<voltage Vout, the detection voltage Vi5 is not transmitted to the external output terminal OUT. In the case where detection voltage Vi5≥voltage Vout, the detection voltage Vi5 is transmitted to the external output terminal OUT.

The operation of the ideal diode ID23 is basically the same as that of the ideal diode ID21. That is, in the case where detection voltage Vi6<voltage Vout, the detection voltage Vi6 is not transmitted to the external output terminal OUT. In the case where detection voltage Vi6≥voltage Vout, the detection voltage Vi6 is transmitted to the external output terminal OUT.

Therefore, the voltage Vout of the external output terminal OUT indicates the same value as the detection voltage indicating the highest value among the detection voltages Vi4 to Vi6. As described above, each of the step-down voltages of the metal resistors R1 to R3 provided for the thermometry units TD21 to TD23 has a positive temperature characteristic. That is, the detection voltage output from the thermometry unit which detects the highest temperature among the thermometry units TD21 to TD23 indicates the highest value. Consequently, the temperature detecting device 2 outputs the detection voltage output from the thermometry unit which detects the highest temperature among the thermometry units TD21 to TD23 as the detection voltage Vout.

As described above, the temperature detecting device 2 is provided with the P-channel MOS transistors MP1 to MP3 coupling the output terminals of the operational amplifiers A1 to A3 and the external output terminal OUT by the gates and the drains. A source-drain voltage in a saturation region in the P-channel MOS transistor is about 0.2V. Consequently, the upper limit of the range in which the detection voltages Vi4 to Vi6 are transmitted to the external output terminal OUT with high precision is a high value to a degree that about 0.2V is subtracted from the power supply voltage Vc2. That is, the temperature detecting device 2 can assure a wide output dynamic range. Therefore, the temperature detecting device 2 can detect the temperatures in the wide range with high precision.

Further, in the temperature detecting device 2, the output terminals of the operational amplifiers A1 to A3 are coupled to the gate electrodes of the P-channel MOS transistors MP1 to MP3. Consequently, a current path extending through the output terminals of the operational amplifiers A1 to A3 and the transistors MP1 to MP3 is not formed. As a result, the operational amplifiers A1 to A3 can have a simple configuration of low output current capability, so that the temperature detecting device 2 can realize smaller scale, lower cost, and lower power consumption.

Although the case where the three thermometry units TD21 to TD23 are provided has been described as an example in the embodiment, the invention is not limited to the case. For example, the configuration can be changed to a configuration that arbitrary number which is two or larger of thermometry units are provided. In this case, operational amplifiers and transistors of the number according to the number of the thermometry units are provided.

Although the case of using the metal resistors R1 to R3 as temperature detecting elements has been described as an example in the embodiment, the invention is not limited to the case. For example, as the temperature detecting element, a PTC thermistor may be used in place of the metal resistor.

Although the case where the temperature detecting device 2 is comprised of the voltage detecting device 200 together with the thermometry units TD21 to TD23 has been described in the embodiment, the invention is not limited to the case. The voltage detecting device 200 may be used as a single body or may be used together with another voltage detecting circuit. The voltage detecting device 200 can detect a voltage indicating the highest value from a plurality of voltages in a wide range with high precision. Smaller scale, lower cost, and lower power consumption can be also realized.

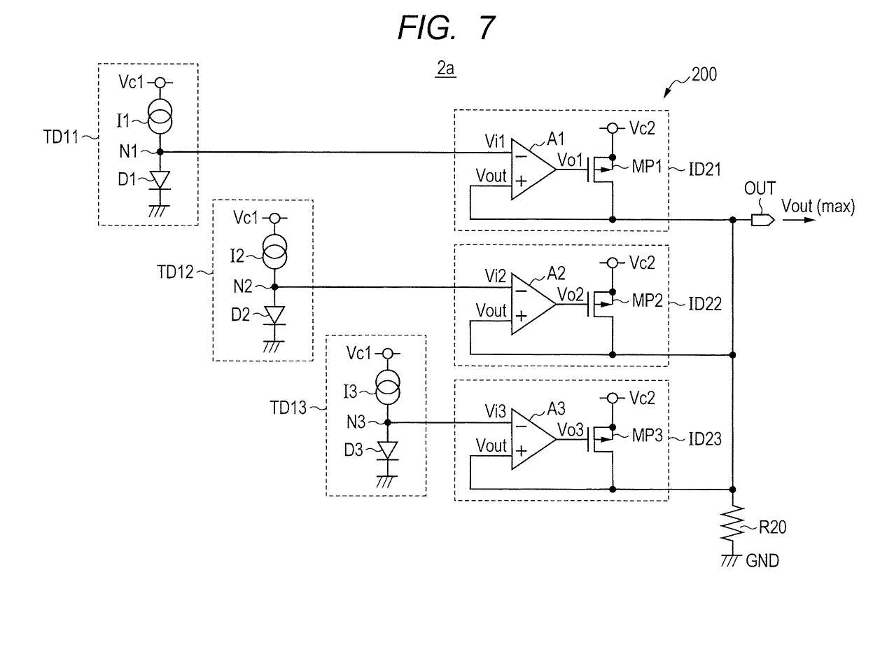

Further, although the case that the temperature detecting device 2 outputs, as the detection voltage Vout, the detection voltage output from the thermometry unit which detects the highest temperature among the plurality of the thermometry units has been described as an example, the invention is not limited to the case. The configuration of the temperature detecting device 2 can be properly changed to a configuration that the detection voltage output from a thermometry unit which detects the lowest temperature among a plurality of thermometry units is output as the detection voltage Vout. Hereinafter, it will be concretely described by using FIG. 7.

### Modification of Temperature Detecting Device 2

FIG. 7 is a block diagram illustrating a modification of the temperature detecting device 2 as a temperature detecting device 2a.

In comparison to the temperature detecting device 2, the temperature detecting device 2a has the thermometry units TD11 to TD13 generating the detection voltages Vi1 to Vi3 having a negative temperature characteristic in place of the thermometry units TD21 to TD23 generating the detection voltages Vi4 to Vi6 having a positive temperature characteristic. Hereinafter, it will be concretely described.

As the details of the thermometry units TD11 to TD13 are already disclosed in FIG. 1, the description will not be repeated.

The voltage Vout of the external output terminal OUT indicates the same value as the detection voltage indicating the highest value among the detection voltages Vi4 to Vi6 output from the thermometry units TD11 to TD13, respectively. As described above, any of the step-down voltages of the diodes D1 to D3 provided for the thermometry units TD11 to TD13 has a negative temperature characteristic. That is, the detection voltage output from the thermometry unit which detects the lowest temperature among the thermometry units TD11 to TD13 indicates the highest value. Consequently, the temperature detecting device 2a outputs the detection voltage output from the thermometry unit which detects the lowest temperature among the thermometry units TD11 to TD13 as the detection voltage Vout.

The temperature detecting device 2a also can produce effects similar to those in the case of the temperature detecting device 2. That is, since a wide output dynamic range can be assured, the temperature detecting device 2a can precisely detect the temperatures in a wide range. Further, since the operational amplifiers A1 to A3 have the simple configuration with low output current capability, the temperature detecting device 2a can realize smaller scale, lower cost, and lower power consumption.

Although the case of using the diodes as the temperature detecting elements has been described as an example in the example of FIG. 7, the invention is not limited to the case. For example, as the temperature detecting element, an NTC thermistor may be used in place of the metal resistor.

### Third Embodiment

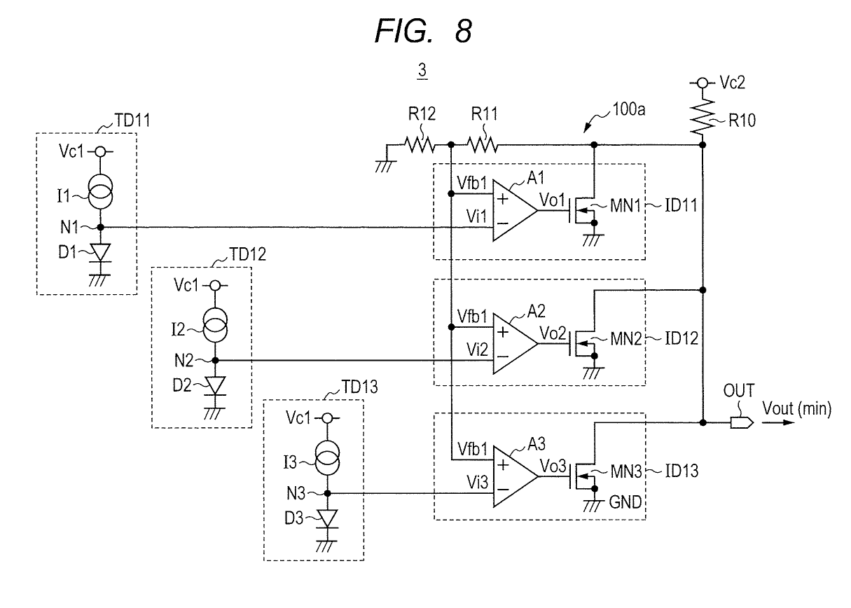

FIG. 8 is a block diagram illustrating a configuration example of a temperature detecting device 3 according to a third embodiment.

In comparison to the temperature detecting device 1, the temperature detecting device 3 has, in place of the voltage detecting device 100, a voltage detecting device 100a in which the amplification factor of the ideal diodes ID11 to ID13 is larger than that in the voltage detecting device 100. Hereinafter, it will be concretely described.

The voltage detecting device 100a further has resistive elements R11 and R12 in addition to the configuration of the voltage detecting device 100. The resistive element R11 is provided between the external output terminal OUT and the non-inversion input terminal of each of the operational amplifiers A1 to A3. The resistive element R12 is provided between the non-inversion input terminal of each of the operational amplifiers A1 to A3 and the reference voltage terminal GND. That is, the resistive elements R11 and R12 perform resistive voltage division on the voltage Vout of the external output terminal OUT to generate a voltage Vfb1. The voltage Vfb1 is fed back to the non-inversion input terminal of each of the operational amplifiers A1 to A3.

As the other configuration of the voltage detecting device 100a is similar to that in the case of the voltage detecting device 100, the description will not be repeated.

Subsequently, the operation of the voltage detecting device 100a will be described.

First, the operation of the ideal diode ID11 will be described.

For example, in the case where detection voltage Vi1>voltage Vfb1 (=Vout×R12/(R11+R12)), the voltage Vo1 of the L level is output from the operational amplifier A1, so that the transistor MN1 is turned off. That is, a negative feedback path of the operational amplifier A1 is interrupted. Consequently, the voltage Vout is maintained at a value indicated until then without being influenced by the detection voltage Vi1. In other words, the detection voltage Vi1 is not transmitted to the external output terminal OUT.

On the other hand, in the case where detection voltage Vi1≤voltage Vfb1, the voltage Vo1 of the H level is output from the operational amplifier A1, so that the transistor MN1 is turned on. That is, a negative feedback path of the operational amplifier A1 is formed. Consequently, by adjusting the voltage Vo1 by the operational amplifier A1, the voltage Vout is adjusted so as to indicate the same value as the detection voltage Vi1. In other words, by adjusting the voltage Vo1 by the operational amplifier A1, the voltage Vout is adjusted so as to satisfy Vi1×(R11+R12)/R12. That is, in the case where detection voltage Vi1≤voltage Vfb1, the voltage obtained by amplifying the detection voltage Vi1 by (R11+R12)/R12 times is transmitted to the external output terminal OUT.

The operation of the ideal diode ID12 is basically the same as that of the ideal diode ID11. That is, in the case where detection voltage Vi2>voltage Vfb1, the detection voltage Vi2 is not transmitted to the external output terminal OUT. In the case where detection voltage Vi2≤voltage Vfb1, the voltage obtained by amplifying the detection voltage Vi2 by the (R11+R12)/R12 times is transmitted to the external output terminal OUT.

The operation of the ideal diode ID13 is basically the same as that of the ideal diode ID11. That is, in the case where detection voltage Vi3>voltage Vfb1, the detection voltage Vi3 is not transmitted to the external output terminal OUT. In the case where detection voltage Vi3≤voltage Vfb1, the voltage obtained by amplifying the detection voltage Vi3 by the (R11+R12)/R12 times is transmitted to the external output terminal OUT.

Therefore, the voltage Vout of the external output terminal OUT indicates the value obtained by amplifying the lowest detection voltage among the detection voltages Vi1 to Vi3 by the (R11+R12)/R12 times. As described above, each of the step-down voltages of the diodes D1 to D3 provided for the thermometry units TD11 to TD13 has a negative temperature characteristic. That is, the detection voltage output from the thermometry unit which detects the highest temperature among the thermometry units TD11 to TD13 indicates the lowest value. Consequently, the temperature detecting device 3 amplifies the detection voltage output from the thermometry unit which detects the highest temperature among the thermometry units TD11 to TD13 by the (R11+R12)/R12 times and outputs the resultant voltage as the detection voltage Vout.

As described above, the temperature detecting device 3 can produce effects equivalent to those of the temperature detecting device 1 and, moreover, by making the amplification factor of the ideal diodes ID11 to ID13 larger, can improve temperature detection precision.

The amplification factor of the ideal diodes ID11 to ID13 can be arbitrarily set by changing the resistance values of the resistive elements R11 and R12.

### Modification of Temperature Detecting Device 3

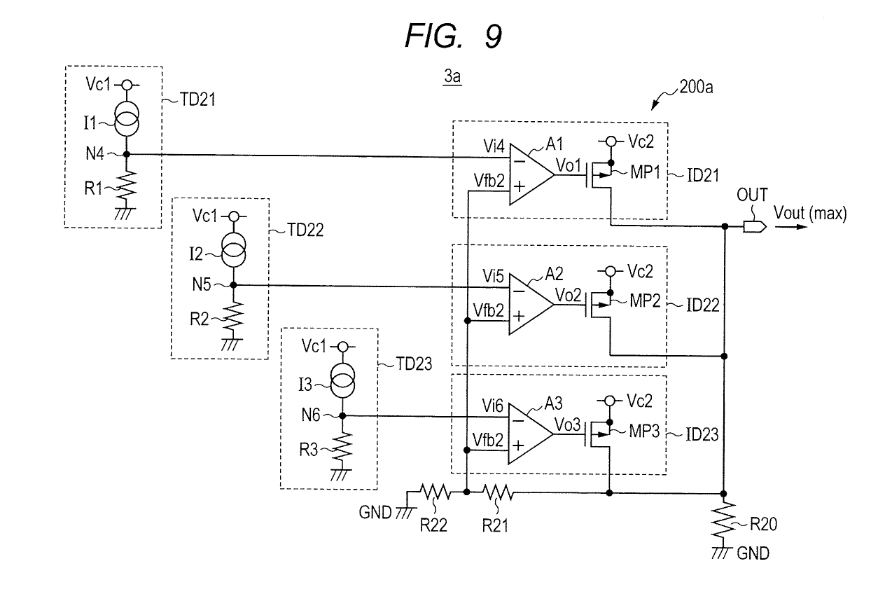

FIG. 9 is a block diagram illustrating a modification of the temperature detecting device 3 as a temperature detecting device 3a.

In comparison to the temperature detecting device 2, the temperature detecting device 3a has a voltage detecting device 200a in which the amplification factor of each of the ideal diodes ID21 to ID23 is larger than that in the voltage detecting device 200. Hereinafter, it will be concretely described.

The voltage detecting device 200a further includes resistive elements R21 and R22 in addition to the configuration of the voltage detecting device 200. The resistive element R21 is provided between the external output terminal OUT and the non-inversion input terminal of each of the operational amplifiers A1 to A3. The resistive element R22 is provided between the non-inversion input terminal of each of the operational amplifiers A1 to A3 and the reference voltage terminal GND. That is, the resistive elements R21 and R22 perform resistive voltage division on the voltage Vout of the external output terminal OUT to generate a voltage Vfb2. The voltage Vfb2 is fed back to the non-inversion input terminal of each of the operational amplifiers A1 to A3.

As the other configuration of the voltage detecting device 200a is similar to that in the case of the voltage detecting device 200, the description will not be repeated.

Subsequently, the operation of the voltage detecting device 200a will be described.

First, the operation of the ideal diode ID21 will be described.

For example, in the case where detection voltage Vi4<voltage Vfb2 (=Vout×R22/(R21+R22)), the voltage Vo1 of the H level is output from the operational amplifier A1, so that the transistor MP1 is turned off. That is, a negative feedback path of the operational amplifier A1 is interrupted. Consequently, the voltage Vout is maintained at a value indicated until then without being influenced by the detection voltage Vi4. In other words, the detection voltage Vi4 is not transmitted to the external output terminal OUT.

On the other hand, in the case where detection voltage Vi4≥voltage Vfb2, the voltage Vo1 of the L level is output from the operational amplifier A1, so that the transistor MP1 is turned on. That is, a negative feedback path of the operational amplifier A1 is formed. Consequently, by adjusting the voltage Vo1 by the operational amplifier A1, the voltage Vfb2 is adjusted so as to indicate the same value as the detection voltage Vi4. In other words, by adjusting the voltage Vo1 by the operational amplifier A1, the voltage Vout is adjusted so as to satisfy Vi4×(R21+R22)/R22. That is, in the case where detection voltage Vi4≥voltage Vfb2, the voltage obtained by amplifying the detection voltage Vi4 by (R21+R22)/R22 times is transmitted to the external output terminal OUT.

The operation of the ideal diode ID22 is basically the same as that of the ideal diode ID21. That is, in the case where detection voltage Vi5<voltage Vfb2, the detection voltage Vi5 is not transmitted to the external output terminal OUT. In the case where detection voltage Vi5≥voltage Vfb2, the voltage obtained by amplifying the detection voltage Vi5 by the (R21+R22)/R22 times is transmitted to the external output terminal OUT.

The operation of the ideal diode ID23 is basically the same as that of the ideal diode ID21. That is, in the case where detection voltage Vi6<voltage Vfb2, the detection voltage Vi6 is not transmitted to the external output terminal OUT. In the case where detection voltage Vi6≥voltage Vfb2, the voltage obtained by amplifying the detection voltage Vi6 by the (R21+R22)/R22 times is transmitted to the external output terminal OUT.

Therefore, the voltage Vout of the external output terminal OUT indicates the value obtained by amplifying the highest detection voltage among the detection voltages Vi4 to Vi6 by the (R21+R22)/R22 times. As described above, each of the step-down voltages of the metal resistors R1 to R3 provided for the thermometry units TD21 to TD23 has a positive temperature characteristic. That is, the detection voltage output from the thermometry unit which detects the highest temperature among the thermometry units TD21 to TD23 indicates the highest value. Consequently, the temperature detecting device 3a amplifies the detection voltage output from the thermometry unit which detects the highest temperature among the thermometry units TD21 to TD13 by the (R21+R22)/R12 times and outputs the resultant voltage as the detection voltage Vout.

As described above, the temperature detecting device 3a can produce effects equivalent to those of the temperature detecting device 2 and, moreover, by making the amplification factor of the ideal diodes ID21 to ID23 larger, can improve temperature detection precision.

The amplification factor of the ideal diodes ID21 to ID23 can be arbitrarily set by changing the resistance values of the resistive elements R21 and R22.

As described above, each of the voltage detecting devices according to the first to third embodiments is provided with the MOS transistor coupling the output terminal of the operational amplifier used for each of ideal diodes and the external output terminal OUT by the gate and the drain. Consequently, each of the voltage detecting devices according to the first to third embodiments can assure a wide output dynamic range, so that the highest or lowest voltage can be precisely detected from a plurality of voltages in a wide range and output it as the detection voltage Vout.

In addition, since the configuration of the operational amplifiers used for the ideal diodes can be made simple and with low output current capability, the voltage detecting devices according to the first to third embodiments can realize smaller scale, lower cost, and lower power consumption.

Further, also with respect to the temperature detecting devices in which the voltage detecting devices according to the first to third embodiments are mounted, a wide output dynamic range can be assured, so that a temperature in a wide range can be detected with precision. In addition, the operational amplifier used for each of the ideal diodes can have a simple configuration of low output current capability, so that smaller scale, lower cost, and lower power consumption can be realized.

Although the invention achieved by the inventors herein has been concretely described above on the basis of the embodiments, obviously, the present invention is not limited to the foregoing embodiments but can be variously changed without departing from the gist.

For example, in the semiconductor devices according to the foregoing embodiments, the conduction types (p-type or n-type) of the semiconductor substrate, the semiconductor layer, the diffusion layer (diffusion region), and the like may be inverted. Consequently, when one of the n type and the p type is set as a first conduction type and the other conduction type is set as a second conduction type, the first conduction type can be set to the p type and the second conduction type can be set to the n type. On the contrary, the first conduction type can be set to the n type and the second conduction type can be set to the p type.

Although the case where the MOS transistors are provided in the output stage of the operational amplifiers used for the ideal diodes has been described as an example in the first to third embodiments, the invention is not limited to the case. The MOS transistors may be replaced by bipolar transistors. For example, the N-channel MOS transistors (for example, MN1, MN2, and MN3) may be replaced by NPN bipolar transistors. The P-channel MOS transistors (for example, MP1, MP2, and MP3) may be replaced by PNP bipolar transistors. In this case, the base, emitter, and collector of the bipolar transistor are coupled in place of the gate, source, and drain of the MOS transistor, respectively. In this case, although base current steadily flows in the bipolar transistor, since the amount of the base current is very small, the influence on increase in power consumption is small. Since the emitter-collector voltage is about 0.2V, an effect of assuring a wide output dynamic range is also obtained.

Further, a part of a plurality of MOS transistors may be replaced by bipolar transistors. That is, the MOS transistors and the bipolar transistors may mixedly exist.

What is claimed is:

1. A voltage detecting device comprising:
a first operational amplifier having an inversion input terminal to which a first detection voltage is supplied and a non-inversion input terminal to which a voltage corresponding to a voltage of an external output terminal is supplied;
a first MOS transistor provided between the external output terminal and a reference voltage terminal and having a gate to which an output voltage of the first operational amplifier is applied;
a second operational amplifier having an inversion input terminal to which a second detection voltage is supplied and a non-inversion input terminal to which a voltage corresponding to the voltage of the external output terminal is supplied; and
a second MOS transistor provided between the external output terminal and the reference voltage terminal and having a gate to which an output voltage of the second operational amplifier is applied.

2. The voltage detecting device according to claim 1, wherein each of the first and second operational amplifiers comprises:
a constant current supply;
a first differential transistor provided between the constant current supply and the reference voltage terminal and having a gate to which a voltage corresponding to the voltage of the external output terminal is applied;
a second differential transistor coupled in parallel to the first differential transistor and having a gate to which the first or second detection voltage is applied;
a first mirror transistor coupled to the first differential transistor in series; and
a second mirror transistor coupled to the second differential transistor in series and to which current proportional to current flowing in the first mirror transistor flows,
wherein a voltage of a node between the second differential transistor and the second mirror transistor is output.

3. A temperature detecting device comprising:
a first thermometry unit generating the first detection voltage according to temperature of a first object to be measured;
a second thermometry unit generating the second detection voltage according to temperature of a second object to be measured; and
a voltage detecting device according to claim 1.

4. The temperature detecting device according to claim 3,
wherein the first thermometry unit comprises a first temperature detecting element generating the first detection voltage indicating a negative temperature characteristic with respect to the temperature of the first object to be measured,
wherein the second thermometry unit comprises a second temperature detecting element generating the second detection voltage indicating a negative temperature characteristic with respect to the temperature of the second object to be measured, and
wherein any of the first and second MOS transistors is an N-channel MOS transistor.

5. The temperature detecting device according to claim 4, wherein any of the first and second temperature detecting elements is a diode or an NCT thermistor in which predetermined current flows.

6. The temperature detecting device according to claim 3,
wherein the first thermometry unit has a first temperature detecting element generating the first detection voltage indicating a positive temperature characteristic with respect to temperature of the first object to be measured,
wherein the second thermometry unit has a second temperature detecting element generating the second detection voltage indicating a positive temperature characteristic with respect to the temperature of the second object to be measured, and
wherein any of the first and second MOS transistors is a P-channel MOS transistor.

7. The temperature detecting device according to claim 6, wherein any of the first and second temperature detecting elements is a metal resistor or a PTC thermistor in which predetermined current flows.

8. A semiconductor device comprising:
a driver switching on/off of a switch element provided between a power supply and a load;
a control circuit controlling the driver;
a power supply circuit supplying power supply voltage to the driver and the control circuit; and
a temperature detecting device according to claim 3, in which the driver is set as the first object to be measured, and the power supply circuit is set as the second object to be measured.

9. A semiconductor device comprising:
a driver switching on/off of a switch element provided between a power supply and a load;
a control circuit controlling the driver;
a power supply circuit supplying power supply voltage to the driver and the control circuit; and
a temperature detecting device,
wherein the temperature detecting device comprises:
a first thermometry unit generating a first detection voltage according to temperature of the driver;
a second thermometry unit generating a second detection voltage according to temperature of the power supply circuit;
a first operational amplifier having an inversion input terminal to which the first detection voltage is supplied and a non-inversion input terminal to which a voltage corresponding to a voltage of an external output terminal is supplied;
a first MOS transistor provided between the external output terminal and a reference voltage terminal and having a gate to which an output voltage of the first operational amplifier is applied;
a second operational amplifier having an inversion input terminal to which the second detection voltage is supplied and a non-inversion input terminal to which a voltage corresponding to the voltage of the external output terminal is supplied; and
a second MOS transistor provided between the external output terminal and the reference voltage terminal and having a gate to which an output voltage of the second operational amplifier is applied.

10. The semiconductor device according to claim 9, wherein each of the first and second operational amplifiers comprises:
a constant current supply;
a first differential transistor provided between the constant current supply and the reference voltage terminal and having a gate to which a voltage corresponding to the voltage of the external output terminal is applied;
a second differential transistor coupled in parallel to the first differential transistor and having a gate to which the first or second detection voltage is applied;
a first mirror transistor coupled to the first differential transistor in series; and
a second mirror transistor coupled to the second differential transistor in series and to which current proportional to current flowing in the first mirror transistor flows, and
wherein a voltage of a node between the second differential transistor and the second mirror transistor is output.

11. The semiconductor device according to claim 9,
wherein the first thermometry unit comprises a first temperature detecting element generating the first detection voltage indicating a negative temperature characteristic with respect to the temperature of the driver,
wherein the second thermometry unit comprises a second temperature detecting element generating the second detection voltage indicating a negative temperature characteristic with respect to the temperature of the power supply circuit, and
wherein any of the first and second MOS transistors is an N-channel MOS transistor.

12. The semiconductor device according to claim 9,
wherein the first thermometry unit has a first temperature detecting element generating the first detection voltage indicating a positive temperature characteristic with respect to temperature of the driver,
wherein the second thermometry unit has a second temperature detecting element generating the second detection voltage indicating a positive temperature characteristic with respect to temperature of the power supply circuit, and
wherein any of the first and second MOS transistors is a P-channel MOS transistor.

13. A load driving device comprising:
a switch element provided between a power supply and a load; and
a semiconductor device according to claim 9 controlling on/off of the switch element.

14. A voltage detecting method comprising the steps of:
amplifying a potential difference between a first detection voltage supplied to an inversion input terminal and a voltage corresponding to a voltage of an external output terminal supplied to a non-inversion input terminal by using a first operational amplifier;
controlling on/off of a first MOS transistor provided between the external output terminal and a reference voltage terminal in accordance with a result of amplification of the first operational amplifier;
amplifying a potential difference between a second detection voltage supplied to an inversion input terminal and a voltage corresponding to a voltage of the external output terminal supplied to a non-inversion input terminal by using a second operational amplifier; and
controlling on/off of a second MOS transistor provided between the external output terminal and the reference voltage terminal in accordance with a result of amplification of the second operational amplifier.

15. The voltage detecting method according to claim 14,
wherein each of the first and second operational amplifiers comprises:
a constant current supply;
a first differential transistor provided between the constant current supply and the reference voltage terminal and having a gate to which a voltage corresponding to the voltage of the external output terminal is applied;
a second differential transistor coupled in parallel to the first differential transistor and having a gate to which the first or second detection voltage is applied;
a first mirror transistor coupled to the first differential transistor in series; and
a second mirror transistor coupled to the second differential transistor in series and to which current proportional to current flowing in the first mirror transistor flows, and
wherein a voltage of a node between the second differential transistor and the second mirror transistor is output.

16. A temperature detecting method comprising the steps of:
generating the first detection voltage according to temperature of a first object to be measured by a first thermometry unit;
generating the second detection voltage according to temperature of a second object to be measured by a second thermometry unit; and
detecting temperature corresponding to a detection voltage indicating a maximum value or a minimum value in the first and second detection voltages by using the voltage detecting method according to claim 14.
